(19) United States
(12) Patent Application Publication
(10) Pub. No.: US 2026/0002253 A1
(43) Pub. Date: Jan. 1, 2026

(54) METHOD OF MANUFACTURING OXIDE THIN FILM

(71) Applicants: Samsung Electronics Co., Ltd., Suwon-si (KR); KOREA ADVANCED INSTITUTE OF SCIENCE AND TECHNOLOGY, Daejeon (KR)

(72) Inventors: Hyungjun KIM, Suwon-si (KR); Sanghun JEON, Daejeon (KR); Hunbeom SHIN, Daejeon (KR); Boeun PARK, Suwon-si (KR); Jeongil BANG, Suwon-si (KR); Jaeho LEE, Suwon-si (KR)

(73) Assignees: Samsung Electronics Co., Ltd., Suwon-si (KR); KOREA ADVANCED INSTITUTE OF SCIENCE AND TECHNOLOGY, Daejeon (KR)

(21) Appl. No.: 19/251,093

(22) Filed: Jun. 26, 2025

(30) Foreign Application Priority Data
Jun. 28, 2024 (KR) 10-2024-0085754

(51) Int. Cl. C23C 14/58; C23C 16/56

(52) U.S. Cl. CPC C23C 14/5806; C23C 16/56

(57) ABSTRACT

Provided are a manufacturing method of an oxide thin film and an apparatus including the oxide thin film. The manufacturing method of the oxide thin film includes forming an amorphous oxide layer on a base layer, raising a temperature of the amorphous oxide layer using microwaves at a first pressure, and forming a crystal structure in the oxide thin film by cooling the temperature-raised oxide layer at a second pressure different from the first pressure.

### CROSS-REFERENCE TO RELATED APPLICATION

This application is based on and claims priority under 35 U.S.C. § 119 to Korean Patent Application No. 10-2024-0085754, filed on Jun. 28, 2024, in the Korean Intellectual Property Office, the disclosure of which is incorporated by reference herein in its entirety.

### BACKGROUND

### 1. Field

The disclosure relates to a method of manufacturing an oxide thin film, and more particularly, to a method of manufacturing an oxide thin film by using microwaves and an apparatus including the oxide thin film.

### 2. Description of the Related Art

Oxide thin films, based on e.g., composition and crystal structure, may have conductive, dielectric, or semiconductive properties according to electrical characteristics. Oxide thin films may have a crystal structure corresponding to a manufacturing process. For example, a dielectric thin film may have ferroelectric, antiferroelectric, or paraelectric properties according to a crystal structure. Ferroelectrics refer to a material having ferroelectricity to maintain spontaneous polarization by aligning internal electric dipole moments with no electric field applied from the outside.

However, when manufacturing oxide thin films, there may be difficulties in crystallization due to the undesired oxidation of layers other than oxide thin films.

### SUMMARY

Provided is a method of manufacturing an oxide thin film by using microwaves.

Provided is a method of manufacturing an oxide thin film by varying a process pressure.

Additional aspects will be set forth in part in the description which follows and, in part, will be apparent from the description, or may be learned by practice of the presented embodiments of the disclosure.

According to an aspect of the disclosure, a manufacturing method of an oxide thin film includes forming an amorphous oxide layer on a base layer, the amorphous oxide layer having an amorphous phase, raising a temperature of the amorphous oxide layer using microwaves at a first pressure, and forming a crystal structure in the oxide thin film by cooling the temperature-raised oxide layer at a second pressure different from the first pressure.

The second pressure may be greater than the first pressure.

The second pressure may be at least 30 atm greater than the first pressure.

The first pressure may be within a range of about 0.001 atm to about 2 atm.

The first pressure may be within a range of about 0.01 atm to about 2 atm.

The raising of the temperature of the oxide layer may include raising the temperature of the oxide layer to within a range of about 200° C. to about 500° C.

The microwaves may have a frequency band of about 2 GHz to about 6 GHz.

The manufacturing method may further include maintaining a temperature of the temperature-raised oxide layer for a first period of time.

The first period of time may further include changing a variable pressure applied to the temperature-raised oxide layer during the first period of time.

The changing the variable pressure may include increasing the variable pressure during the first period of time.

A minimum value of the variable pressure may be the first pressure.

A maximum value of the variable pressure may be the second pressure.

A dielectric constant of the oxide thin film may be 30 or greater.

The temperature-raised oxide layer may include a first crystal structure, and the oxide thin film may include a second crystal structure which is different from the first crystal structure.

A dominant crystal structure of the oxide thin film may be an orthorhombic crystal structure.

A remanent polarization change rate of the oxide thin film may be 12% or less.

The oxide layer may include a metal oxide.

The oxide layer may include at least one of hafnium (Hf), zirconium (Zr), aluminum (Al), calcium (Ca), cerium (Ce), dysprosium (Dy), erbium (Er), gadolinium (Gd), germanium (Ge), lanthanum (La), scandium (Sc), strontium (Sr), tin (Sn), and yttrium (Y).

The oxide layer may include Hf₁₋ₓMₓO₂ (0<x<1, M: any one of zirconium (Zr), aluminum (Al), calcium (Ca), cerium (Ce), dysprosium (Dy), erbium (Er), gadolinium (Gd), germanium (Ge), lanthanum (La), scandium (Sc), silicon (Si), strontium (Sr), tin (Sn), and yttrium (Y)).

The base layer may be a conductor or a semiconductor.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart illustrating a manufacturing method of an oxide thin film by using microwaves, according to at least one embodiment;

FIGS. 2A to 2E are each a diagram illustrating an example of a crystal structure of an oxide layer in a manufacturing process of an oxide thin film;

FIG. 3A is a diagram illustrating conditions of temperature and pressure when forming an oxide thin film by using microwaves at 0.01 atm;

FIG. 3B is a diagram illustrating a polarization-electric field (P-E) curve of an oxide thin film formed under the conditions of FIG. 3A;

FIG. 3C is a diagram illustrating a voltage-current curve of an oxide thin film formed under the conditions of FIG. 3A;

FIG. 4A is a diagram illustrating conditions of temperature and pressure when forming an oxide thin film by using microwaves at 1 atm;

FIG. 4B is a diagram illustrating a polarization-electric field (P-E) curve of an oxide thin film formed under the conditions of FIG. 4A;

FIG. 4C is a diagram illustrating a voltage-current curve of an oxide thin film formed under the conditions of FIG. 4A;

FIG. 5A is a diagram illustrating a condition of temperature and pressure when an oxide thin film has been formed by performing temperature-raising and cooling at different pressures from each other, according to at least one embodiment;

FIG. 5B is a diagram illustrating a polarization-electric field (P-E) curve of an oxide thin film formed under the condition of FIG. 5A;

FIG. 5C is a diagram illustrating a voltage-current curve of an oxide thin film formed under the condition of FIG. 5A;

FIG. 6A is a diagram illustrating another condition of temperature and pressure when an oxide thin film has been formed by performing temperature-raising and cooling at different pressures from each other, according to at least one embodiment;

FIG. 6B is a diagram illustrating a polarization-electric field (P-E) curve of an oxide thin film formed under the condition of FIG. 6A;

FIG. 6C is a diagram illustrating a voltage-current curve of an oxide thin film formed under the condition of FIG. 6A;

FIG. 7 is a mimetic diagram schematically illustrating a field-effect transistor according to at least one embodiment;

FIG. 8 is a mimetic diagram schematically illustrating a field-effect transistor according to at least one embodiment;

FIG. 9 is a cross-sectional diagram illustrating a schematic structure of a memory apparatus according to at least one embodiment;

FIG. 10 is a diagram illustrating an electronic device according to at least one embodiment;

FIG. 11 is a mimetic diagram illustrating an electronic apparatus according to at least one embodiment;

FIG. 12 is a diagram illustrating an electronic apparatus according to at least one embodiment;

FIG. 13 is a cross-sectional view taken along line A-A′ of FIG. 12;

FIG. 14 is a conceptual diagram schematically illustrating a device architecture applicable to an apparatus according to at least one embodiment; and

FIG. 15 is a conceptual diagram schematically illustrating a device architecture applicable to an apparatus according to at least one embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a manufacturing method of an oxide thin film according to various embodiments and an apparatus including the same are described in detail with reference to the accompanying drawings. In the drawings, like reference numerals in the drawings denote like elements, and sizes of components in the drawings may be exaggerated for clarity and convenience of explanation.

An expression used in the singular encompasses the expression of the plural, unless it has a clearly different meaning in the context. When a portion “includes” a component, another component may be further included, rather than excluding the existence of the other component, unless otherwise described. Sizes or thicknesses of components in the drawings may be exaggerated for convenience of explanation. Further, when a certain material layer is described as being arranged on a substrate or another layer, the material layer may be in contact with the other layer, or there may be a third layer between the material layer and the other layer. In embodiments, materials constituting each layer are provided merely as an example, and other materials may also be used. It will also be understood that such spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

Moreover, the terms “part,” “module,” etc., refer to a functional unit configured to process and/or enable at least one function or operation, and may be implemented by and/or include processing circuitry such as a hardware, a software, or a combination thereof. For example, the processing circuitry may include, but is not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc., and/or, as described in further detail below, may include active and/or passive elements such as transistors, gates, capacitors, resistors, and/or the like.

The particular implementations shown and described herein are illustrative examples of embodiments and are not intended to otherwise limit the scope of embodiments in any way. For the sake of brevity, conventional electronics, control systems, software development and other functional aspects of the systems may not be described in detail.

Furthermore, the connecting lines, or connectors shown in the various figures presented are intended to represent exemplary functional relations and/or physical or logical couplings between the various elements. It should be noted that many alternative or additional functional relations, physical connections or logical connections may be present in a practical device.

The use of the terms “a” and “an” and “the” and similar referents in the context of describing embodiments (especially in the context of the following claims) are to be construed to cover both the singular and the plural.

The expression such as “at least” used to list elements is intended to limit a list of entire elements, rather than individual elements in the list. For example, expressions such as “at least one of A, B, and C” or “at least one selected from the group consisting of A, B, and C” may be interpreted as only A, only B, only C, or a combination of two or more of A, B, and C, e.g., ABC, AB, BC, and AC.

When the terms such as “about” or “substantially” are used in relation to numerical values, the relevant numerical value may be construed as including a manufacturing or operation deviation (e.g., ±10%) of the stated numerical value. In addition, when the expressions such as “generally” and “substantially” are used in relation to a geometric shape, the geometric precision may not be required, and the intention is that the degree of tolerance regarding the shape is within the scope of embodiments of the disclosure. Moreover, regardless of whether a numerical value of a shape is limited by using “about” or “substantially”, such numerical value or shape should be understood as including a manufacturing or operation deviation (e.g., ±10%) of the stated numerical value. Additionally, whenever a range of values is enumerated, the range includes all values within the range as if recorded explicitly clearly, and may further include the boundaries of the range. Accordingly, “within the range of ‘X’ to ‘Y’” and/or “‘X’ to ‘Y’” includes all values between X and Y, including X and Y.

While such terms as “first,” “second,” etc., may be used to describe various components, such components must not be limited to the above terms. The above terms are used only to distinguish one component from another.

The use of any and all examples, or exemplary language provided herein, is intended merely to better illuminate technical ideas and does not pose a limitation on the scope of embodiments unless otherwise claimed.

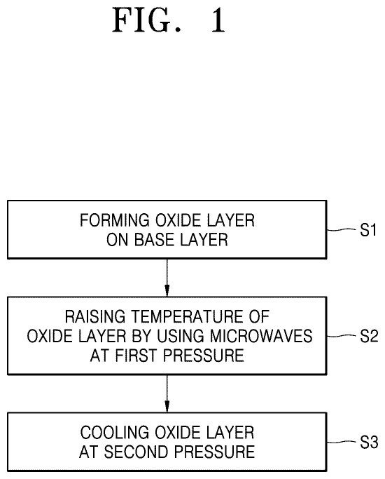

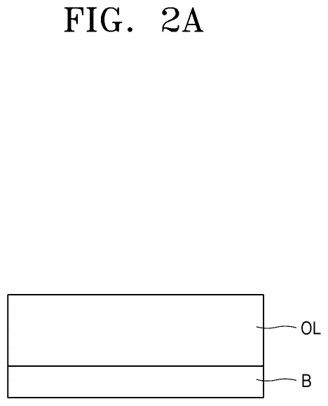

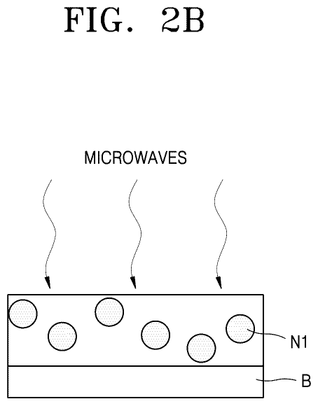

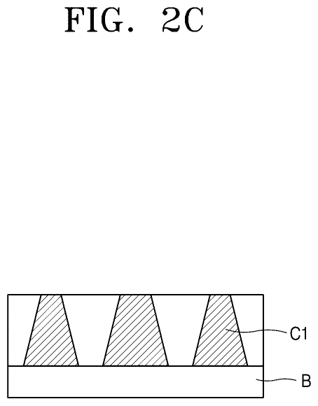

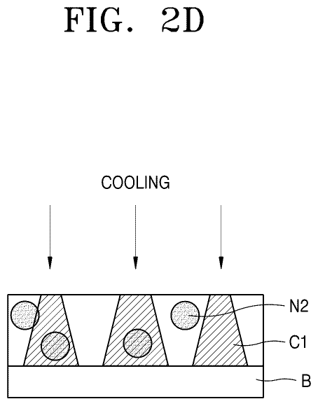

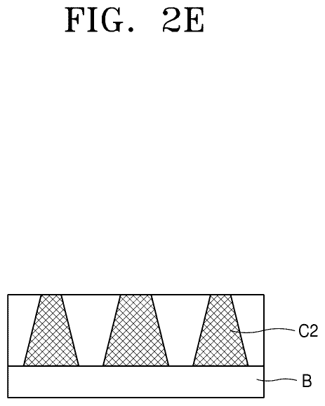

FIG. 1 is a flowchart illustrating a manufacturing method of an oxide thin film OF by using microwaves, according to at least one embodiment, and FIGS. 2A to 2E are each a diagram illustrating an example of a crystal structure C of an oxide layer OL in a manufacturing process of the oxide thin film OF.

Referring to FIGS. 1 and 2A, the oxide layer OL may be formed on a base layer B (S1). The base layer B may be a conductor or a semiconductor. However, the disclosure is not limited thereto. For example, the base layer B may be a dielectric.

The oxide layer OL may include a metal oxide. For example, the oxide layer OL may include an oxide of at least one of hafnium (Hf), zirconium (Zr), aluminum (Al), calcium (Ca), cerium (Ce), dysprosium (Dy), erbium (Er), gadolinium (Gd), germanium (Ge), lanthanum (La), scandium (Sc), strontium (Sr), tin (Sn), yttrium (Y). For example, the oxide layer OL may include at least one of HfO₂ and/or Hf₁₋ₓMₓO₂ (0<x<1), wherein M is at least one of zirconium (Zr), aluminum (Al), calcium (Ca), cerium (Ce), dysprosium (Dy), erbium (Er), gadolinium (Gd), germanium (Ge), lanthanum (La), scandium (Sc), silicon (Si), strontium (Sr), tin (Sn), and/or yttrium (Y)). The thickness of the oxide layer OL may be about 20 nm or less and/or about 10 nm or less.

The oxide layer OL may be deposited at room temperature. The oxide layer OL may be formed on a substrate through a deposition method (such as chemical vapor deposition (CVD), atomic layer deposition (ALD), physical vapor deposition (PVD), etc.). The deposited oxide layer OL may be an amorphous phase.

The temperature of the oxide layer OL may be raised by using the microwaves at a first pressure (S2). The first pressure may be about 2 atmospheres (atm) or less, about 1 atm or less, about 0.1 atm or less, about 0.01 atm or greater, and/or about 0 atm or greater. For example, the first pressure may be within a range of about 0.01 atm to about 2 atm and/or about 0.001 atm to about 2 atm. The first pressure may be a pressure having a certain range or a fixed value.

The microwave may be about 2 gigahertz (GHz) or greater, about 2.5 GHz or grater, and/or about 3 GHz or greater, and/or about 5 GHz or less, about 6 GHz or less, and/or about 7 GHz or less. For example, the microwave may have a frequency band of about 2 GHz to about 6 GHZ.

When the microwave is provided to the oxide layer OL, polar molecules and/or dipoles of the oxide layer OL may absorb the microwave and vibrate. Due to the vibration, heat may be generated from the oxide layer OL, and the crystallization of the oxide layer OL may be initiated and/or propagated by the generated heat. In at least some embodiments, microwave may be selected based on the oxide layer OL and/or other materials on the base layer B. For example, the microwave may be focused onto the oxide layer OL and/or the other materials may be selected to be less and/or non-reactive to the microwave. As the oxide layer OL itself becomes a heat source, the thermal efficiency and speed of temperature increase may be high, compared to the case where the heating is caused by external thermal conduction. In addition, the oxide layer OL may be crystalized at a relatively low temperature.

Referring to FIG. 2B, nucleation sites N1 may be formed inside the oxide layer OL due to the heat. The nucleation sites N1 may also be referred to as nukes. Referring to FIG. 2C, as the process temperature increases, the generated nuke N1 may grow and may be crystalized into a particular crystal structure C1. The crystal structure C1 of the oxide layer OL may vary according to the process pressure and the process temperature. The dominant crystal structure of the temperature-raised oxide layer OL according to at least one embodiment may be a tetragonal crystal structure. In this regard, the dominant crystal structure may refer to the most frequent crystal structure of the oxide layer OL.

The temperature of the oxide layer OL raised by the microwave may be lower than a temperature raised by a higher frequency radiation (such as a laser, x-ray, EUV, etc.). For example, the temperature of the oxide layer OL raised by the microwave may be about 150° C. or higher, about 200° C. or higher, about 250° C. or higher, and/or about 300° C. or higher, and/or about 400° C. or lower, about 450° C. or lower, and/or about 500° C. or lower. For example, the raised temperature of the oxide layer OL may be about 200° C. to about 500° C. The raised temperature of the oxide layer OL may refer to a temperature of the oxide layer OL itself or a temperature of a chamber where the oxide layer OL is arranged.

As the raised temperature of the oxide layer OL is low, oxidation of layers other than the oxide layer OL in the process of temperature increase may be prevented or reduced. For example, when the substrate is a metal layer, the oxide layer OL may be selectively crystalized without the deterioration (e.g., oxidation) of the metal layer.

In the process of raising the temperature of the oxide layer OL, a first variable pressure which changes over time may be provided as the process pressure. The first variable pressure may be a pressure which gradually increases over time. A minimum value of the first variable pressure may be greater than or equal to the first pressure. The time during which the first variable pressure is provided may be shorter than the time during which the first pressure is provided. For example, the oxide layer may be formed on the substrate under the first pressure, and the oxide layer OL may be heated by microwaves while the first pressure is maintained. When the temperature of the oxide layer OL reaches a first temperature, the process pressure may be changed to the first variable pressure and provided until the temperature of the oxide layer OL reaches a second temperature which is higher than the first temperature. The second temperature may also be referred to as a raised temperature or a target temperature. However, the disclosure is not limited thereto. The first pressure may be provided until the temperature of the oxide layer OL reaches the second temperature.

After the temperature of the oxide layer OL reaches the target temperature, by cooling the oxide layer OL at a second pressure which is different from a first pressure, the oxide thin film OF may be formed (S3). The oxide layer OL may be cooled to the temperature before the temperature raise, for example, to room temperature. However, the disclosure is not limited thereto. The oxide layer OL may be cooled to a temperature lower than or equal to the room temperature. The cooling of the oxide layer OL may be performed by suspending the provision of microwaves; and/or the cooling of the oxide layer OL may be performed by suspending the provision of microwaves and supplying a cooling gas thereto. For convenience, the cooled oxide layer OL may be referred to as the oxide thin film OF. The oxide thin film OF may have a crystal structure. The thickness of the oxide thin film OF may be about 20 nm or less and/or about 10 nm or less.

The second pressure may be greater than the first pressure. For example, the second pressure may be at least about 30 atm and/or about 50 atm greater than the first pressure. When the temperature of the oxide layer OL drops at a high pressure like the second pressure, phase transition may occur in the crystalized oxide layer OL.

In some embodiments, when the temperature of the oxide layer OL reaches the target temperature, the temperature of the oxide layer may be maintained for a certain time period. The time period during which the temperature of the oxide layer OL is maintained may vary according to a material, thickness, etc. of the oxide layer. During when the temperature of the oxide layer OL is maintained at a target temperature, a third variable pressure which changes over time may be supplied as a process pressure. The third variable pressure may be a pressure which gradually increases over time. A minimum value of the third variable pressure may be the first pressure, and a maximum value of the third variable pressure may be the second pressure. The time period during which the third variable pressure is provided may be shorter than or equal to the time period during which the temperature of the oxide layer OL is maintained at the target temperature.

Referring to FIG. 2D, when the temperature of the oxide layer OL decreases at the second pressure, a nuke N2 having a different crystal structure than the predetermined crystal structure C1 may be formed in the oxide layer OL. For example, the nuke N2 of the crystal structure may be a nuke of a monoclinic crystal structure or a nuke of an orthorhombic crystal structure.

When the temperature of the oxide layer OL keeps decreasing under the second pressure which is a high pressure, as illustrated in FIG. 2E, the generated nuke N2 may grow and the oxide layer OL may be crystalized into a crystal structure C2 that is different from the crystal structure C1 generated in the process of heat raise. That is, the oxide layer OL may undergo a phase-transition. In at least some embodiments, the dominant crystal structure C2 of the oxide thin film OF may be an orthorhombic crystal structure.

The dielectric constant of the oxide thin film OF may be different from a dielectric constant of the oxide layer OL crystalized in the process of heat raise. The dielectric constant of the oxide thin film OF may be greater than a dielectric constant of the oxide layer OL crystalized in the process of heat raise. For example, the dielectric constant of the oxide thin film OF may be about 30 or greater, about 40 or greater, and/or about 50 or greater. The oxide layer OL formed according to at least one embodiment may be a dielectric.

In the process of cooling the oxide layer OL, a second variable pressure which changes over time may be further provided as the process pressure. The second variable pressure may be a pressure which gradually increases over time. A maximum value of the second variable pressure may be less than or equal to the second pressure. For example, simultaneously with the suspended provision of the microwaves to the oxide layer OL, the second variable pressure may be provided as the process pressure. After the second variable pressure gradually increases over time and reaches the second pressure, the second pressure may be maintained until the temperature of the oxide layer OL reaches the room temperature. The time during which the second variable pressure is provided may be shorter than the time during which the second pressure is provided.

As the oxide thin film OF according to at least one embodiment is cooled and formed at a high pressure, the electrical stability of the oxide thin film OF may be improved. That is, even though an electrical signal is repeatedly applied to an apparatus including the oxide thin film OF, the electrical characteristics of the oxide thin film OF (for example, polarization characteristics) may be maintained within a certain range. Despite the repeated application of an electrical signal described above, when the electrical characteristics of the oxide thin film OF are constant, the oxide thin film OF may be construed as being in a wake-up free state.

The oxide thin film OF according to at least one embodiment may have remanent polarization of about 15 μC/cm² or greater, and the remanent polarization change amount may be about 12% or less or about 10% or less. In addition, the oxide thin film OF according to at least one embodiment may have a leakage current of about 10⁻⁷ A/cm² when a voltage of 1 V is applied.

As described in relation to FIG. 1, the oxide thin film OF may be formed by performing the temperature-raising process and the cooling process one time. However, the disclosure is not limited thereto. The oxide thin film OF may be formed by a plurality of temperature-raising processes and cooling processes.

When the oxide layer is crystalized at a low pressure, a crystal structure of the oxide layer may vary according to the pressure. To observe a crystal structure of an oxide layer, an oxide layer including Hf_{0.5}Zr_{0.5}O was formed at room temperature on a metal layer including TiN. The thickness of the oxide layer was about 10 nm. By forming the metal layer including TiN on the oxide layer, a capacitor was formed. Then, the structure of TiN/Hf_{0.5}Zr_{0.5}O/TiN was annealed by using microwaves.

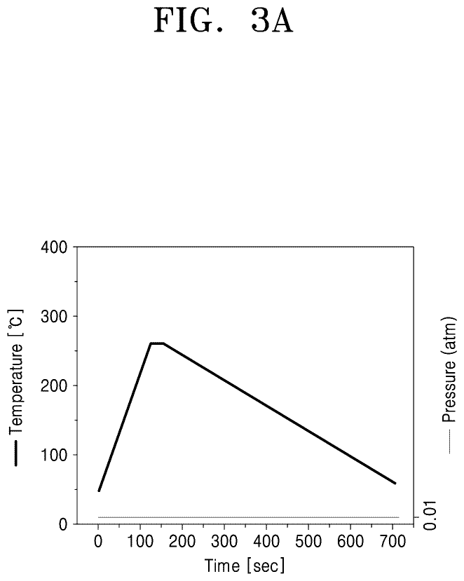

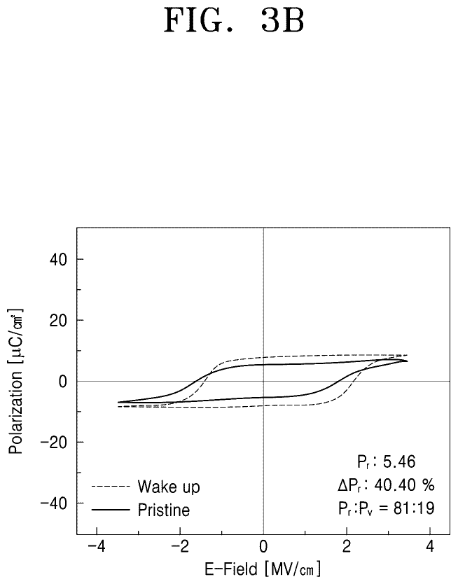

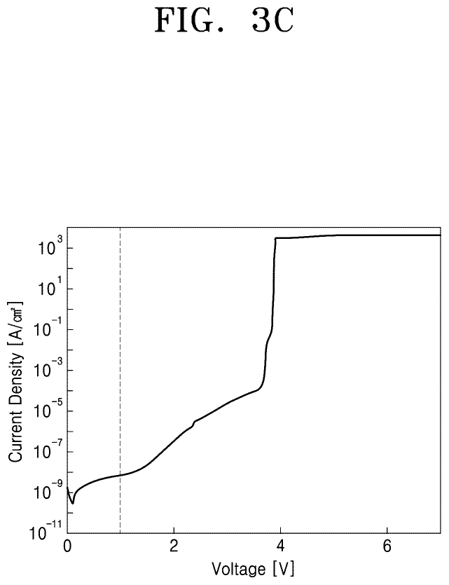

FIG. 3A is a diagram illustrating conditions of temperature and pressure when forming an oxide thin film by using microwaves at 0.01 atm, FIG. 3B is a diagram illustrating a polarization-electric field (P-E) curve of an oxide thin film formed under the conditions of FIG. 3A, and FIG. 3C is a diagram illustrating a voltage-current curve of an oxide thin film formed under the conditions of FIG. 3A.

Referring to FIG. 3A, while maintaining the process pressure at 0.01 atm, the temperature of the oxide layer was raised to about 250° C. by using microwaves, and then the oxide layer was cooled to form an oxide thin film. When the temperature of the oxide layer reached 250° C., the temperature of the oxide layer was maintained for a certain time period, for example, about 50 seconds or less and/or about 100 seconds or less. The time period during which the temperature of the oxide layer is maintained may vary according to a component, thickness, etc. of the oxide layer. FIG. 3B illustrates a polarization-electric field (P-E) curve of an oxide thin film formed under the conditions of FIG. 3A. Referring to FIG. 3B, a remanent polarization (Pr) may be about 5.46 microcoulombs per centimeter squared (μC/cm²), a change rate (ΔPr) of the remanent polarization may be 40.40%, and the remanent polarization (Pr): variable polarization (Pv) may be 81:19. From the P-E curve, it may be expectable that the crystal structure of the oxide thin film formed at a process pressure of 0.01 atm may include a crystal structure corresponding to paraelectric materials.

Referring to FIG. 3C, when a voltage of about 1V is applied to the oxide thin film, a leakage current of 7.09×10⁻⁹ A/cm² may flow.

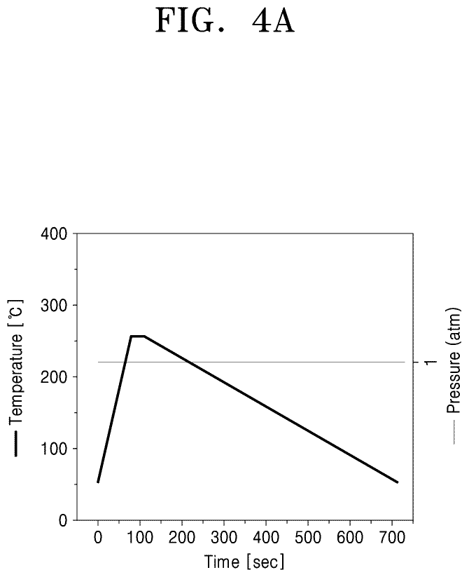

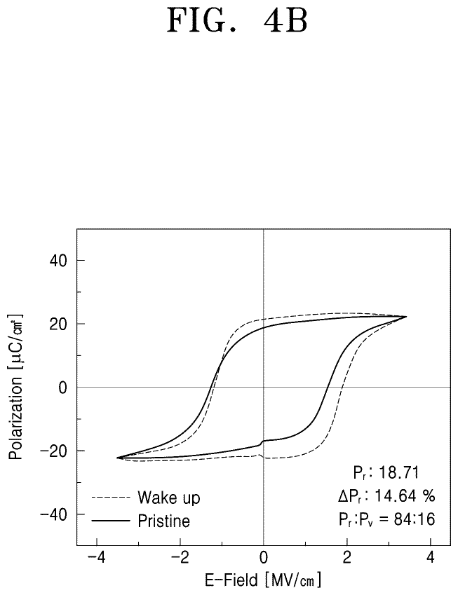

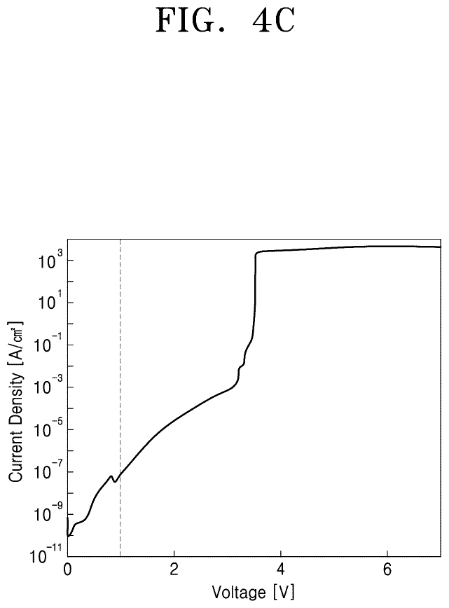

FIG. 4A is a diagram illustrating conditions of temperature and pressure when forming an oxide thin film by using microwaves at 1 atm, FIG. 4B is a diagram illustrating a P-E curve of an oxide thin film formed under the conditions of FIG. 4A, and FIG. 4C is a diagram illustrating a voltage-current curve of an oxide thin film formed under the conditions of FIG. 4A.

Referring to FIG. 4A, while maintaining the process pressure at 1 atm, the temperature of the oxide layer was raised to about 250° C. by using microwaves, and then the oxide layer was cooled to form an oxide thin film. When the temperature of the oxide layer reached 250° C., the temperature of the oxide layer was maintained for a certain time period, for example, about 50 seconds or less or about 100 seconds or less. FIG. 4B illustrates a P-E curve of an oxide thin film formed under the conditions of FIG. 4A. Referring to FIG. 4B, a remanent polarization (Pr) may be about 18.71 μC/cm², a change rate (ΔPr) of the remanent polarization may be 14.64%, and the remanent polarization (Pr): variable polarization (Pv) may be 84:16. From the P-E curve, it may be expectable that the oxide thin film formed at a process pressure of 1 atm may include an antiferroelectric and a ferroelectric that are mixed with each other.

Referring to FIG. 4C, when a voltage of about 1V is applied to the oxide thin film, a leakage current of 8.08×10⁻⁸ A/cm² may flow.

When comparing FIGS. 3B and 4B, it is confirmed that under a low process pressure, the crystal structure of the oxide thin film may vary according to the process pressure. In addition, the greater the process pressure is, the greater the remanent polarization of the oxide thin film may be. From this, it may be expected that the oxide thin film has ferroelectric characteristics.

In the oxide thin film according to at least one embodiment, as the temperature of the oxide layer is raised at a low pressure and is cooled at a high pressure, the ferroelectric characteristics of the oxide thin film may be strengthened, and the stability of the oxide thin film may be improved.

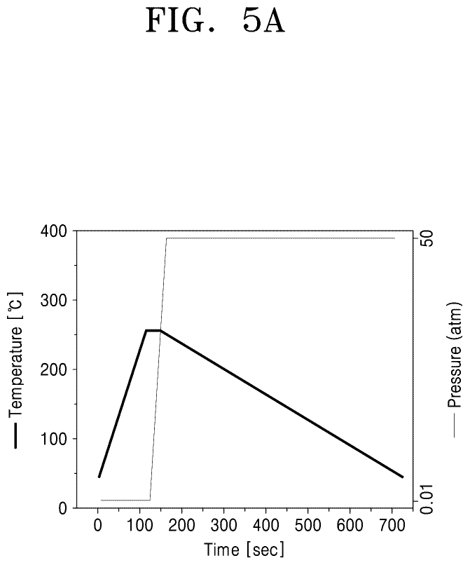

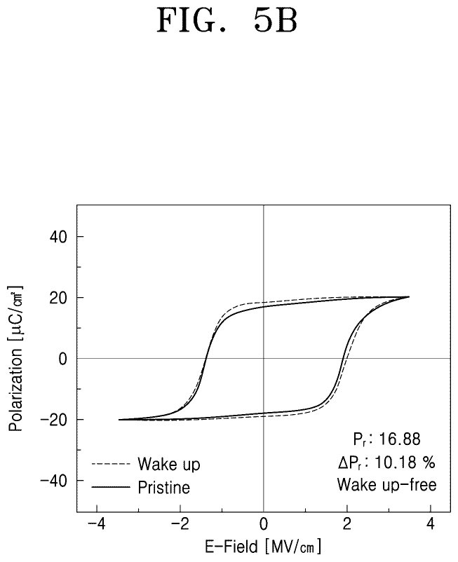

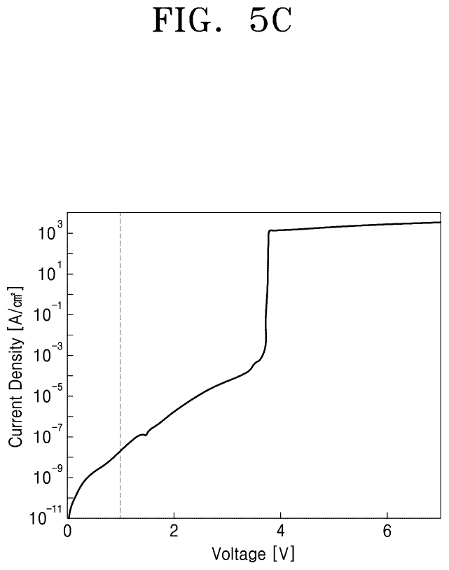

FIG. 5A is a diagram illustrating a condition of temperature and pressure when an oxide thin film has been formed by performing temperature-raising and cooling at different pressures from each other, according to at least one embodiment, FIG. 5B is a diagram illustrating a P-E curve of an oxide thin film formed under the condition of FIG. 5A, and FIG. 5C is a diagram illustrating a voltage-current curve of an oxide thin film formed under the condition of FIG. 5A.

Referring to FIG. 5A, at the process pressure of 0.01 atm, the temperature of the oxide layer was raised to about 250° C. by using microwaves, and then the temperature of the oxide layer was maintained for a certain time period. At the time when the temperature of the oxide layer is cooled, the process pressure may be increased to about 50 atm. For example, at a particular time point during when the temperature of the oxide layer is maintained at 250° C., the process pressure may be gradually increased, and when the process pressure reaches about 50 atm, the temperature of the oxide layer may be cooled.

FIG. 5B illustrates a P-E curve of an oxide thin film formed under the condition of FIG. 5A. Referring to FIG. 5B, a remanent polarization (Pr) may be about 16.88 μC/cm², and a change rate (ΔPr) of the remanent polarization may be 10.18%. The change rate of the remanent polarization was improved.

It is found that the P-E curve (Pristine curve) of the oxide thin film for the first electrical application to the oxide thin film is mostly similar to the P-E curve (Wave up curve) of the oxide thin film for the second electrical application to the oxide thin film. This may mean that the oxide thin film may stably operate despite repeated application of electrical signals to the oxide thin film.

Referring to FIG. 5C, when a voltage of about 1V is applied to the oxide thin film, a leakage current of 2.71×10⁻⁸ A/cm² may flow.

When comparing FIGS. 3B, 3C, 5B, and 5C, it is found that even though the temperature of the oxide layer was raised at a low pressure, as the oxide layer was cooled at a high pressure, the electrical characteristics of the oxide thin film was improved. As a high pressure is provided during a part of the process procedures for the oxide thin film, e.g., the process of cooling the oxide layer, damages on layers due to a high pressure may be reduced or prevented. When the oxide thin film is manufactured in a low pressure state, the manufacturing time was about 700 seconds, whereas the manufacturing time was reduced to about 300 seconds when the oxide thin film was manufactured at a high pressure.

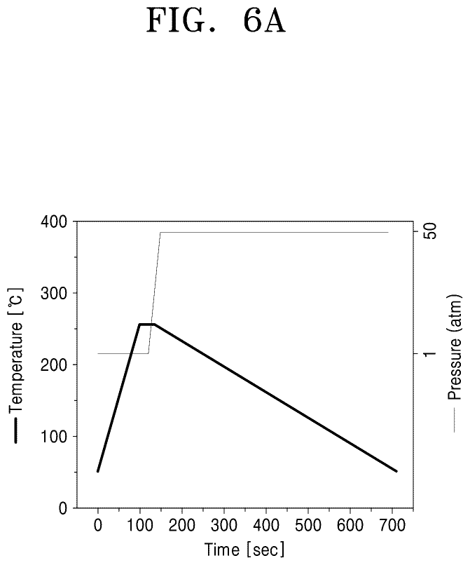

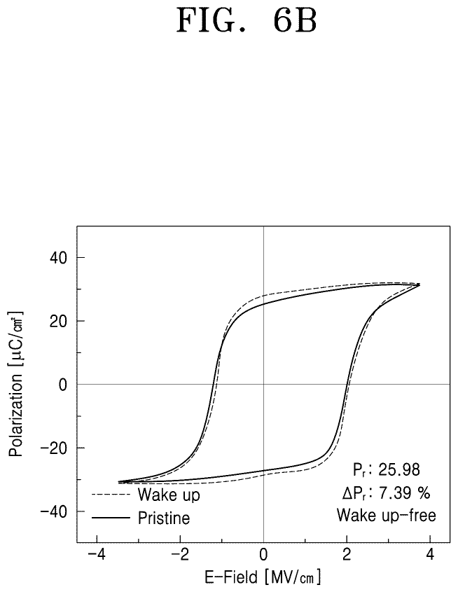

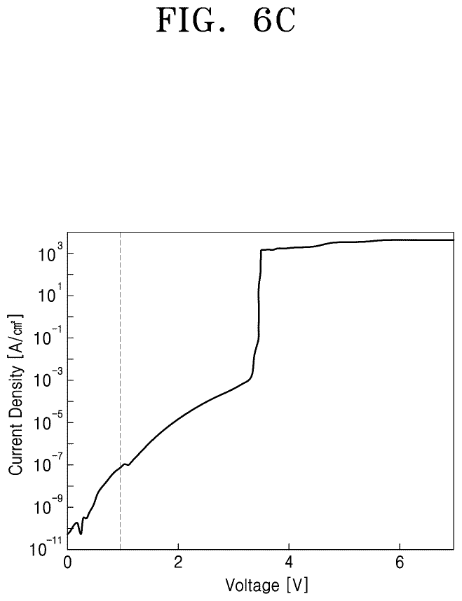

FIG. 6A is a diagram illustrating another condition of temperature and pressure when an oxide thin film has been formed by performing temperature-raising and cooling at different pressures from each other, according to at least one embodiment, FIG. 6B is a diagram illustrating a P-E curve of an oxide thin film formed under the condition of FIG. 6A, and FIG. 6C is a diagram illustrating a voltage-current curve of an oxide thin film formed under the condition of FIG. 6A.

Referring to FIG. 6A, the temperature of the oxide layer was raised by using microwaves at a process pressure of about 1 atm. When the temperature of the oxide layer had reached about 250° C., the temperature of the oxide layer was maintained for a certain time period. At a particular time point during the time when the temperature of the oxide layer was maintained at 250° C., for example, 30 seconds after the temperature of the oxide layer reached 250° C., the process pressure was gradually increased. Then, when the process pressure reaches 50 atm, the oxide layer was cooled.

FIG. 6B illustrates a P-E curve of an oxide thin film formed under the conditions of FIG. 6A. Referring to FIG. 6B, a remanent polarization (Pr) may be about 25.98 μC/cm², and a change rate (ΔPr) of the remanent polarization may be 7.39%. The change rate of the remanent polarization was improved.

It is found that the P-E curve (Pristine curve) of the oxide thin film for the first electrical application to the oxide thin film is mostly similar to the P-E curve (Wave up curve) of the oxide thin film for the second electrical application to the oxide thin film. This may mean that the oxide thin film may stably operate despite repeated application of electrical signals to the oxide thin film.

Referring to FIG. 6C, when a voltage of about 1V is applied to the oxide thin film, a leakage current of 7.82×10⁻⁸ A/cm² may flow.

When comparing FIGS. 4B, 4C, 6B, and 6C, it is found that even though the temperature of the oxide layer was raised at a low pressure, as the oxide layer was cooled at a high pressure, the electrical characteristics of the oxide thin film was improved. As a high pressure is provided during a part of the process procedures for the oxide thin film, e.g., the process of cooling the oxide layer, damages on layers due to a high pressure may be reduced or prevented.

The pressure at the time of temperature-raising and the pressure at the time of cooling according to at least one embodiment may vary. The pressure at the time of temperature-raising may include at least one of an increased pressure and a decreased pressure, and the pressure at the time of cooling may also include at least one of an increased pressure and a decreased pressure. An average pressure at the time of cooling according to at least one embodiment may be greater than an average pressure at the time of temperature-raising. For example, the average pressure at the time of cooling may be at least about 20 atm, about 30 atm, or about 50 atm greater than the average pressure at the time of temperature-raising. The pressure profile may be set differently according to a final desired crystal structure of the oxide thin film.

The oxide thin film with improved electrical characteristics according to at least one embodiment may be used as a material of a semiconductor device, for example, a dielectric layer. The semiconductor device may be a memory device or a non-memory device, and for example, may be a field-effect transistor, a capacitor, or a combined structure thereof; however, the disclosure is not limited thereto.

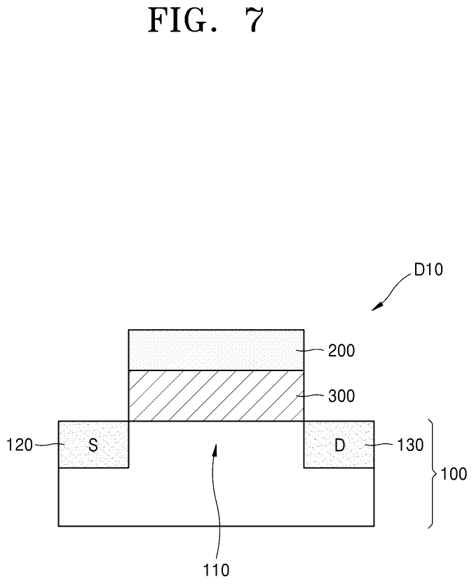

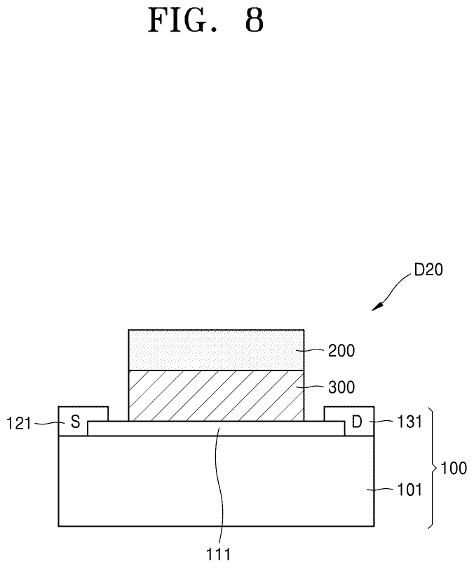

FIGS. 7 and 8 are each a mimetic diagram schematically illustrating a field-effect transistor according to at least one embodiment. Referring to FIGS. 7 and 8, a field-effect transistor (D10 and D20) may include a substrate 100 including a source (120 and 121) and a drain (130 and 131), a gate electrode 200 arranged on the substrate 100, and a ferroelectric layer 300 arranged between the substrate 100 and the gate electrode 200.

The substrate 100 may include a semiconductor material. For example, the substrate 100 may include Si, Ge, SiGe, group III-V materials, etc., and may be changed into various forms such as a silicon-on-insulator (SOI), etc.

The substrate 100 may include the source (120 and 121) and the drain (130 and 131), and a channel (110 and 111) electrically connected to the source (120 and 121) and the drain (130 and 131). The source (120 and 121) may be electrically connected to or in contact with a first end of the channel (110 and 111), and the drain (130 and 131) may be electrically connected to or in contact with a second end of the channel (110 and 111).

Referring to FIG. 7, the channel 110 may be defined as an area between the source 120 and the drain 130 in the substrate 100. The source 120 and the drain 130 may be formed by injecting impurities into areas of the substrate 100 which are different from each other.

In addition, referring to FIG. 8, the channel 111 may be implemented as a material layer (thin film) separate from a substrate area 101. The channel 111 may include various component materials. For example, the channel 111 may include at least one semiconductor material such as an elemental semiconductor (Si, Ge, SiGe, etc.), one of the group III-V materials, an oxide semiconductor, a nitride semiconductor, an oxynitride semiconductor, a two-dimensional (2D) material, a quantum dot, an organic semiconductor, a combination thereof, and/or the like. For example, the oxide semiconductor may include InGaZnO, etc., and the 2D material may include a transition metal dichalcogenide (TMD) or a graphene, and the quantum dot may include a colloidal quantum dot, a nanocrystal structure, etc. In addition, the source 121 and the drain 131 may include a conductive material, and may each independently include a metal, a metal compound, or conductive polymer.

The gate electrode 200 may be arranged on and spaced apart from the substrate 100 and may be arranged opposite to the channel (110 and 111). The gate electrode 200 may have a resistance of about 1 Mohm/square or less. The gate electrode 200 may include a conductor, including at least one of a metal, a metal nitride, a metal carbide, polysilicon, a combination thereof, and/or a combination thereof. For example, the metal may include at least one of aluminum (Al), tungsten (W), molybdenum (Mo), titanium (Ti), or tantalum (Ta); and the metal nitride may include a titanium nitride (TiN) and/or a tantalum nitride (TaN), and the metal carbide may be a metal carbide doped with (or containing) aluminum or silicon, and may include, for example, TiAlC, TaAlC, TiSiC or TaSiC. The gate electrode 200 may have a structure in which a plurality of materials are stacked. For example, they may have a stacked structure of metal nitride layer/metal layer or a stacked structure of metal nitride layer/metal carbide layer/metal layer, such as TiN/TiAlC/W. The gate electrode 200 may include a titanium nitride film (TiN film) or molybdenum (Mo), and the above examples may be used in a variety of modified forms.

A dielectric layer 300 may be arranged between the substrate 100 and the gate electrode 200. More specifically, the dielectric layer 300 may be formed on the channel (110 and 111).

The dielectric layer 300 may correspond to an oxide thin film manufactured by the manufacturing method according to at least one embodiment. The dielectric layer 300 may include an orthorhombic crystal structure as a dominant crystal structure. The dielectric layer may include a metal oxide. For example, the dielectric layer may include at least one of hafnium (Hf), zirconium (Zr), aluminum (Al), calcium (Ca), cerium (Ce), dysprosium (Dy), erbium (Er), gadolinium (Gd), germanium (Ge), lanthanum (La), scandium (Sc), strontium (Sr), tin (Sn), and yttrium (Y). For example, the oxide layer may include at least one of HfO₂ and Hf₁₋ₓMₓO₂ (0<x<1, M: any one of zirconium (Zr), aluminum (Al), calcium (Ca), cerium (Ce), dysprosium (Dy), erbium (Er), gadolinium (Gd), germanium (Ge), lanthanum (La), scandium (Sc), silicon (Si), strontium (Sr), tin (Sn), and yttrium (Y)).

The field-effect transistor may be implemented in various forms including 2-dimension, 3-dimension, etc. For example, the field-effect transistor (FET) may have a 1-gate on channel form such as a planer-FET, a 3-gate on channel form such as a Fin-FET, or a 4-gate on channel form such as a gate-all-around-FET.

The semiconductor device (D10 and D20) described above may be applied to various electronic apparatuses, and may be applied as a memory cell in a memory apparatus. The memory apparatus may have a 3D structure, a vertical structure, etc., and may have, for example, a vertical NAND (VNAND) structure.

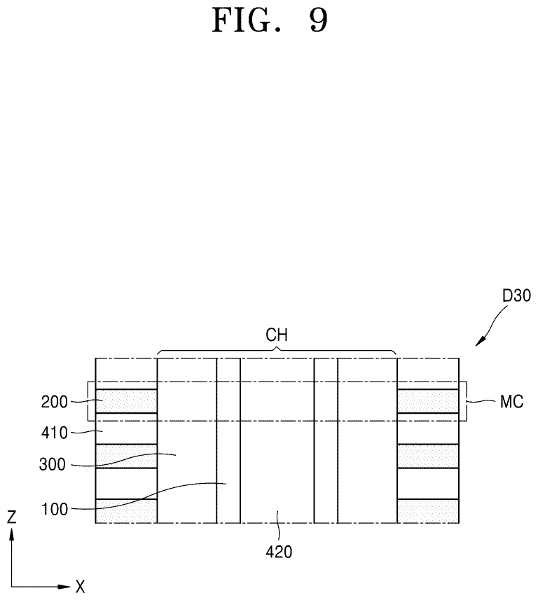

FIG. 9 is a cross-sectional diagram illustrating a schematic structure of a memory apparatus according to at least one embodiment.

A memory apparatus D30 may include a plurality of memory cells MC. The plurality of memory cells MC may be repeatedly arranged in a first direction (e.g., the Z direction). Each of the memory cells may include the gate electrode 200, the dielectric layer 300, and a semiconductor layer. The semiconductor layer may correspond to the substrate 100 in FIGS. 7 and 8, and/or to the base B in FIGS. 2A to 2E, and will be referred to as a semiconductor layer 100, with reference to FIG. 9, for case of understanding.

In at least some embodiments, a plurality of gate electrodes 200 and a plurality of spacers 410 may be alternately arranged in the first direction (e.g., Z direction). The plurality of gate electrodes 200 may each be connected to and/or part of a word line (not shown) or a string select line (not shown).

A channel hole CH vertically penetrating the plurality of gate electrodes 200 and the plurality of spacers 410 which are alternately arranged may be provided. The channel hole CH may include a plurality of layers. The channel hole CH may include a pillar 420 extending in the first direction, the semiconductor layer 100 surrounding a lateral surface of the pillar 420, and the dielectric layer 300 surrounding a lateral surface of the semiconductor layer 100′. The dielectric layer 300 of FIG. 9 may be an oxide thin film manufactured by the manufacturing method according to at least one embodiment.

The pillar 420 may include, e.g., a silicon oxide. One end of the semiconductor layer 100′ may be in contact with a common source area, and another end of the semiconductor layer 100′ may be in contact with a drain (not shown).

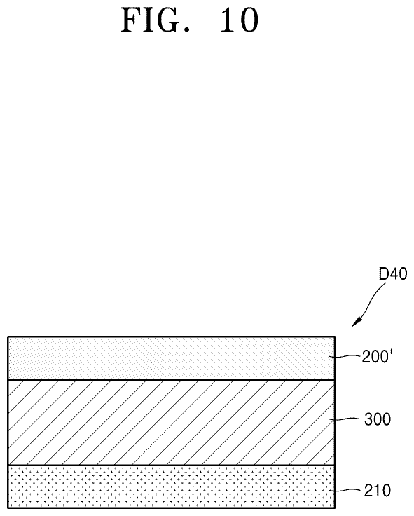

FIG. 10 is a diagram illustrating an electronic device (capacitor) according to at least one embodiment.

Referring to FIG. 10, an electronic device D40 may include a lower electrode 210, an upper electrode 200′ arranged apart from the lower electrode 210, and the dielectric layer 300 arranged between the lower electrode 210 and the upper electrode 200′. In this regard, the dielectric layer 300 may be an oxide thin film manufactured by the method according to at least one embodiment.

The lower electrode 210 may be arranged on a substrate (not shown). The substrate may be a part of a structure supporting the capacitor and/or a part of a device connected to the capacitor. The substrate may include a semiconductor material pattern, an insulating material pattern, and/or a conductive material pattern. The substrate may include, for example, a semiconductor material such as silicon (Si), germanium (Ge), silicon germanium (SiGe), silicon carbide (SiC), gallium arsenide (GaAs), indium arsenide (InAs), indium phosphide (InP), etc., and/or an insulating material such as a silicon oxide, a silicon nitride, a silicon oxynitride, etc.

The upper electrode 200′ may be arranged to be apart from and face the lower electrode 210. The lower electrode 210 and the upper electrode 200′ may each include a conductive material, such as a metal, a conductive nitride, a conductive metal oxide, and/or a combination thereof. For example, the metal may include ruthenium (Ru), titanium (Ti), tantalum (Ta), niobium (Nb), iridium (Ir), molybdenum (Mo), tungsten (W), platinum (Pt), etc. The conductive metal nitride may include, for example, titanium nitride (TiN), tantalum nitride (TaN), niobium nitride (NbN), molybdenum nitride (MoN), cobalt nitride (CON), tungsten nitride (WN), etc. The conductive metal oxide may include, for example, platinum oxide (PtO), iridium oxide (IrO2), ruthenium oxide (RuO2), strontium ruthenium oxide (SrRuO3), barium strontium ruthenium oxide ((Ba,Sr)RuO3), calcium ruthenium oxide (CaRuO3), lanthanum strontium cobalt oxide ((La,Sr)CoO3), etc.

The lower electrode 210 and the upper electrode 200′ may each have a single-material layer or a stacked structure of multiple material layers. For example, the lower electrode 210 and the upper electrode 200′ may each be a single layer including titanium nitride (TiN) or a single layer including niobium nitride (NbN). In at least some embodiments, the lower electrode 210 and the upper electrode 200′ may each have a stacked structure including an electrode layer including titanium nitride (TiN) and/or an electrode layer including niobium nitride (NbN).

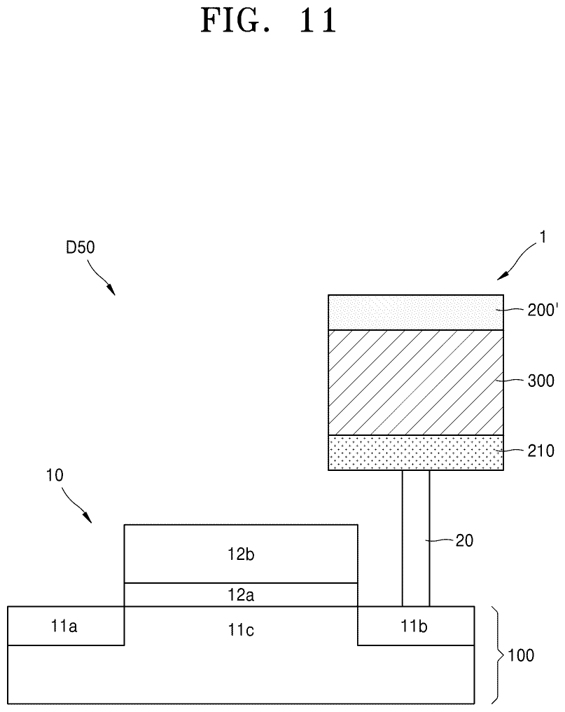

FIG. 11 is a mimetic diagram illustrating an electronic apparatus according to at least one embodiment.

Referring to FIG. 11, an electronic apparatus D50 may include a structure in which a capacitor 1 and a field-effect transistor 10 are electrically connected by a contact 20. The capacitor 1 may include the lower electrode 210, the upper electrode 200′, and the dielectric layer 300 arranged between the lower electrode 210 and the upper electrode 200′. The capacitor 1 may correspond to the capacitor D30 illustrated in FIG. 10, and any redundant description thereon will be omitted. Additionally, the field-effect transistor 10 may correspond to the field-effect transistors D10 and/or D20 in FIGS. 7 and 8.

Alternatively, the field-effect transistor 10 may include the substrate 100 and a gate electrode 12b arranged on the substrate 100. A gate insulating layer 12a may be further arranged between the substrate 100 and the gate electrode 12b.

The substrate 100 may include a source 11a, a drain 11b, and a channel 11c electrically connected to the source 11a and the drain 11b. The source 11a may be electrically connected to or in contact with one end of the channel 11c, and the drain 11b may be electrically connected to or in contact with another end of the channel 11c. The channel 11c may be defined as a substrate area between the source 11a and the drain 11b in the substrate 100.

The substrate 100 may include a semiconductor material. The substrate 100 may include, for example, a semiconductor material, such as silicon (Si), germanium (Ge), silicon germanium (SiGe), silicon carbide (SiC), gallium arsenic (GaAs), indium arsenic (InAs), indium phosphide (InP), etc. In addition, the substrate 100 may include a silicon-on-insulator (SOI) substrate.

The source 11a, the drain 11b, and the channel 11c may each independently be formed by injecting impurities into different areas of the substrate 100, and in this case, the source 11a, the channel 11c, and the drain 11b may include a substrate material as a base material. The source 11a and the drain 11b may include a conductive material, and in this case, the source 11a and the drain 11b may include, for example, a metal, a metal compound, or conductive polymer.

The channel 11c may be implemented as a separate material layer (thin film, not shown). In this case, the channel 11c may include, e.g., at least one Si, Ge, SiGe, group III-V semiconductors, an oxide semiconductor, a nitride semiconductor, an oxynitride semiconductor, a 2D material, a quantum dot, and an organic semiconductor. For example, the oxide semiconductor may include InGaZnO, etc., and the 2D material may include a transition metal dichalcogenide (TMD) or a graphene, and the quantum dot may include a colloidal quantum dot, a nanocrystal structure, etc.

The gate electrode 12b may be arranged on and apart from the substrate 100 and may face the channel 11c. The gate electrode 12b may include at least one of a metal, a metal nitride, a metal carbide, and polysilicon. For example, the metal may include at least one of aluminum (Al), tungsten (W), molybdenum (Mo), titanium (Ti), and tantalum (Ta), and the metal nitride film may include at least one of a TiN film and a TaN film. The metal carbide may include at least one of metal carbides doped with (or containing) aluminum and silicon, e.g., TiAlC, TaAlC, TiSiC, or TaSiC.

The gate electrode 12b may have a structure in which a plurality of materials are stacked, and may have a stacked structure of metal nitride layer/metal layer such as TiN/Al, etc., or a stacked structure of metal nitride layer/metal carbide layer/metal layer such as TiN/TiAlC/W. However, the materials described above are just an example.

The gate insulating layer 12a may be further arranged between the substrate 100 and the gate electrode 12b. The gate insulating layer 12a may include a paraelectric material or a high-k dielectric material and may have a dielectric constant of about 20 to about 70.

The gate insulating layer 12a may include a silicon oxide, a silicon nitride, an aluminum oxide, a hafnium oxide, a zirconium oxide, etc., or a 2D insulator such as a hexagonal boron nitride (h-BN). For example, the gate insulating layer 12a may include silicon oxide (SiO₂), silicon nitride (SiNx), etc., and may include hafnium oxide (HfO2), hafnium silicon oxide (HfSiO4), lanthanum oxide (La2O3), lanthanum aluminum oxide (LaAlO3), zirconium oxide (ZrO2), hafnium zirconium oxide (HfZrO2), zirconium silicon oxide (ZrSiO4), tantalum oxide (Ta2O5), titanium oxide (TiO2), strontium titanium oxide (SrTiO3), yttrium oxide (Y2O3), aluminum oxide (Al2O3), red scandium tantalum oxide (PbSc0.5Ta0.5O3), red zinc niobate (PbZnNbO3), etc. In addition, the gate insulating layer 12a may include a metal oxynitride such as aluminum oxynitride (AlON), zirconium oxynitride (ZrON), hafnium oxynitride (HfON), lanthanum oxynitride (LaON), yttrium oxynitride (YON), etc., a silicate such as ZrSiON, HfSiON, YSiON, LaSiON, etc., or an aluminate such as ZrAlON, HfAlON, etc. In addition, the gate insulating layer 12a may include the oxide thin film described above. The gate insulating layer 12a may constitute a gate stack along with the gate electrode 12b.

One of the electrodes 200 and 210 of the capacitor 1 and one of the source 11a and the drain 11b of the field-effect transistor 10 may be electrically connected to the contact 20. In this regard, the contact 20 may include a proper conductive material, such as tungsten, copper, aluminum, polysilicon, etc.

The arrangement of the capacitor 1 and the field-effect transistor 10 may be variously changed. For example, the capacitor 1 may be arranged on the substrate 100 or may be buried in the substrate 100. Although FIG. 11 illustrates an electronic apparatus D60 including one capacitor 1 and one field-effect transistor 10, the disclosure is not limited thereto. The electronic device may include a plurality of capacitors and a plurality of field-effect transistors.

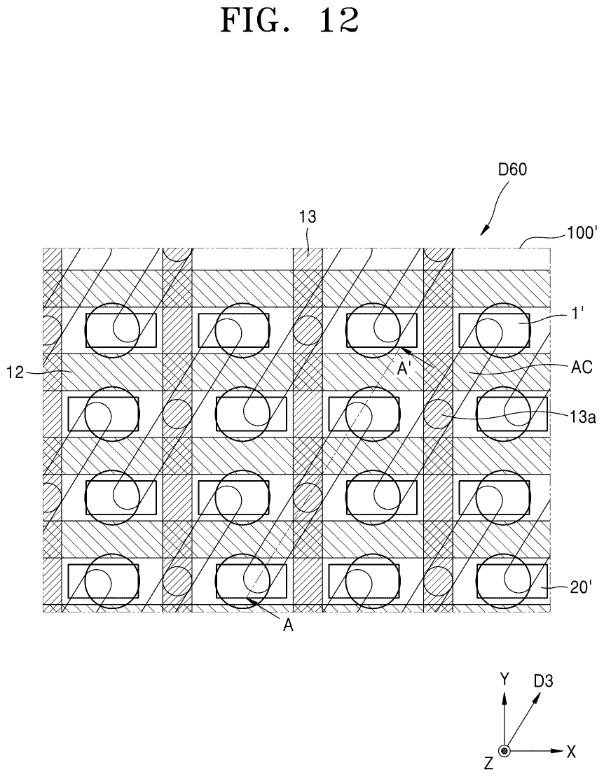

FIG. 12 is a diagram illustrating an electronic apparatus according to at least one embodiment.

Referring to FIG. 12, the electronic apparatus D60 may include a structure in which a plurality of capacitors and a plurality of field-effect transistors are repeatedly arranged. The electronic apparatus D60 may include the substrate 100′ including a source, a drain, and a channel, a field-effect transistor including the gate stack 12, the contact structure 20′ which does not overlap the gate stack 12 and is arranged on the substrate 100′, and the capacitor 1′ arranged on the contact structure 20′, and may further include the bit line structure 13 electrically connecting a plurality of field-effect transistors.

FIG. 12 illustrates a semiconductor apparatus in which the contact structure 20′ and the capacitor 1′ are repeatedly arranged in both X direction and Y direction; however, the disclosure is not limited thereto. For example, the contact structure 20′ may be arranged in the X direction and the Y direction, and the capacitor 1′ may be arranged in a hexagonal shape such as a honeycomb structure.

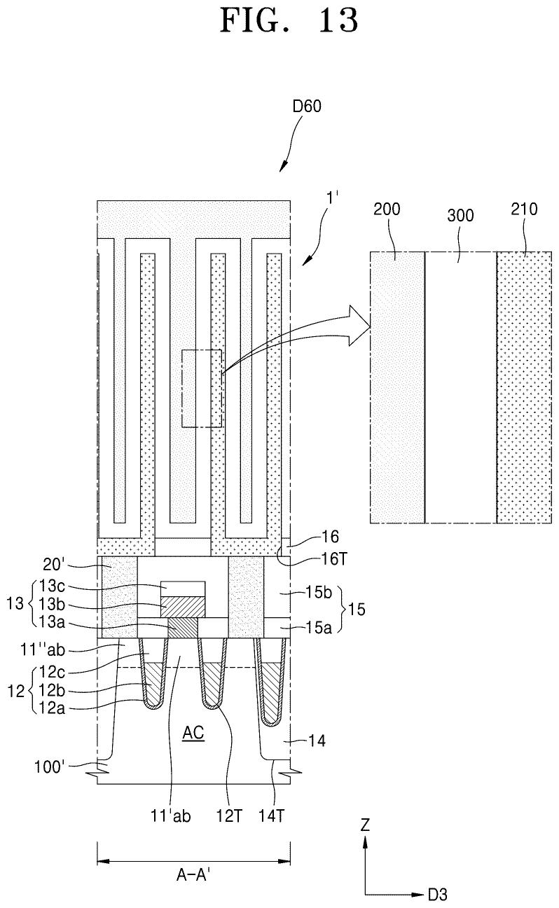

FIG. 13 is a cross-sectional view taken along line A-A′ of FIG. 12.

Referring to FIG. 13, the substrate 100′ may have a shallow trench isolation (STI) structure including a device isolation film 14. The device isolation film 14 may be a single layer including a single type of insulating film or a multi-layer including a combination of two or more insulating films. The device isolation film 14 may include a device isolation trench 14T in the substrate 100′, and the device isolation trench 14T may be filled with an insulating material. The insulating material may include at least one of fluoride silicate glass (FSG), undoped silicate glass (USG), boro-phospho-silicate glass (BPSG), phospho-silicate glass (PSG), flowable oxide (FOX), plasma enhanced tetra-ethyl-ortho-silicate (PE-TEOS), and tonen silazene (TOSZ); however, the disclosure is not limited thereto.

The substrate 100′ may further include an active area AC defined by the device isolation film 14 and a gate line trench 12T arranged to be parallel with an upper surface of the substrate 100′ and extending in the X direction. The active area AC may have a relatively long island shape having a minor axis and a major axis. The major axis of the active area AC may be arranged in the D3 direction which is parallel with the upper surface of the substrate 100′ as illustrated in FIG. 11.

The gate line trench 12T may be arranged to intersect with the active area AC by a certain depth from the upper surface of the substrate 100′ or may be arranged in the active area AC. The gate line trench 12T may be arranged in the device isolation trench 14T, and the gate line trench 12T in the device isolation trench 14T may have a bottom surface that is lower than the gate line trench 12T of the active area AC. A first source/drain 11′ab and a second source/drain 11″ab may be arranged in an upper portion of the active area AC arranged on both sides of the gate line trench 12T.

A gate stack 12 may be arranged in the gate line trench 12T. More specifically, the gate insulating layer 12a, the gate electrode 12b, and a gate capping layer 12c may be sequentially arranged in the gate line trench 12T. The gate insulating layer 12a and the gate electrode 12b may be understood by referring to the descriptions provided above, and the gate capping layer 12c may include at least one of a silicon oxide, a silicon oxynitride, and a silicon nitride. The gate capping layer 12c may be arranged on the gate electrode 12b to fill a remaining portion of the gate line trench 12T.

A bit line structure 13 may be arranged on the first source/drain 11′ab. The bit line structure 13 may be arranged to be parallel with the upper surface of the substrate 100′ and to extend in the Y direction. The bit line structure 13 may be electrically connected to the first source/drain 11′ab and may sequentially include on the substrate a bit line contact 13a, a bit line 13b, and a bit line capping layer 13c. For example, the bit line contact 13a may include polysilicon, the bit line 13b may include a metal material, and the bit line capping layer 13c may include an insulating material such as a silicon nitride or a silicon oxynitride.

FIG. 13 illustrates a case where the bit line contact 13a has a bottom surface having the same level as the uppers surface of the substrate 100′; however, the bit line contact 13a may extend into a recess (not shown) formed at a certain depth from the upper surface of the substrate 100′, and the bottom surface of the bit line contact 13a may be lower than the upper surface of the substrate 100′.

The bit line structure 13 may further include a bit line intermediate layer (not shown) between the bit line contact 13a and the bit line 13b. The bit line intermediate layer may include a metal silicide such as a tungsten silicide or a metal nitride such as a tungsten nitride. In addition, a bit line spacer (not shown) may be further formed on a side wall of the bit line structure 13. The bit line spacer may have a single-layer structure or a multi-layer structure and may include an insulating material such as a silicon oxide, a silicon oxynitride, a silicon nitride, etc. Additionally, the bit line spacer may further include an air spacer (not shown).

The contact structure 20′ may be arranged on the second source/drain 11″ab. The contact structure 20′ and the bit line structure 13 may be arranged on different sources/drains on the substrate. The contact structure 20′ may have a structure in which a lower contact pattern (not shown), a metal silicide layer (not shown), and an upper contact pattern (not shown) are sequentially stacked on the second source/drain 11″ab. The contact structure 20′ may further include a barrier layer (not shown) surrounding a lateral surface and a bottom surface of the upper contact pattern. For example, the lower contact pattern may include polysilicon, the upper contact pattern may include a metal material, and the barrier layer may include a metal nitride having conductivity.

The capacitor 1′ may be electrically connected to the contact structure 20′ and may be arranged on the substrate 100′. More specifically, the capacitor 1′ may include a lower electrode 210 electrically connected to the contact structure 20′, the dielectric layer 300 arranged on the lower electrode 210, and the upper electrode 200′ arranged on the dielectric layer 300. The dielectric layer 300 may be arranged on the lower electrode 210 to be parallel with the surface of the lower electrode 210. As the lower electrode 210, the dielectric layer 300, and the upper electrode 200′ of the capacitor 1′ are already described above, redundant descriptions thereon are omitted.

An interlayer insulating layer 15 may be further arranged between the capacitor 1′ and the substrate 100′. The interlayer insulating layer 15 may be arranged in a space between the capacitor 1′ and the substrate 100′ where no other structure is arranged. More specifically, the interlayer insulating layer 15 may be arranged to cover the wiring of the bit line structure 13, the contact structure 20′, the gate stack 12 on the substrate, and/or an electrode 200 structure. For example, the interlayer insulating layer 15 may surround a wall of the contact structure 20′. The interlayer insulating layer 15 may include a first interlayer insulating layer 15a surrounding the bit line contact 13a and a second interlayer insulating layer 15b covering a lateral surface and/or an upper surface of the bit line 13b and the bit line capping layer 13c.

The lower electrode 210 of the capacitor 1′ may be arranged on the interlayer insulating layer 15, more specifically, on the second interlayer insulating layer 15b. Moreover, when a plurality of capacitors l′ are arranged, bottom surfaces of a plurality of lower electrodes 210 may be separated by an etch stop layer 16. In other words, the etch stop layer 16 may include an opening 16T, and the bottom surface of the lower electrode 210 of the capacitor 1′ may be arranged in the opening 16T. As illustrated in FIG. 13, the lower electrode 210 may have a shape of cylinder with closed bottom or a cup. However, the examples are not limited thereto. For example, the lower electrode may have a pillar shape.

The oxide thin film manufacturing by the manufacturing method according to at least one embodiment may be used as a dielectric layer (e.g., the gate insulating layer 12a and/or the dielectric layer 300); however, the disclosure is not limited thereto. The oxide thin film may be a conductor or a semiconductor, depending on materials and electrical characteristics thereof.

The semiconductor device according to embodiments and an electronic apparatus including the same may be applicable in various fields. For example, the electronic device or electronic apparatus according to embodiments may be used as a logic device or a memory device. The electronic device and electronic apparatus according to embodiments may be used for arithmetic operations, execution of programs, temporary data maintenance, etc. in apparatuses such as a mobile device, a computer, a notebook, a sensor, a network device, a neuromorphic device, etc. In addition, the electronic device and the electronic apparatus according to embodiments may be useful for apparatuses continuously performing a large-scale data transmission.

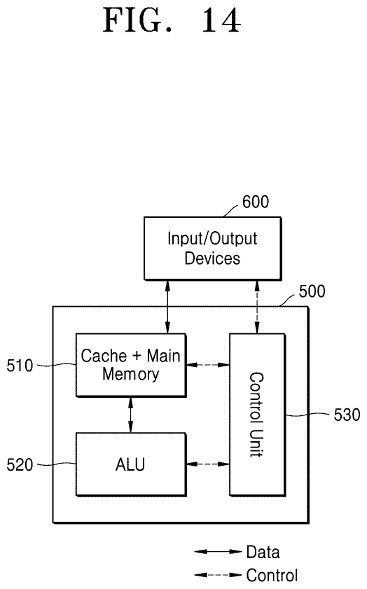

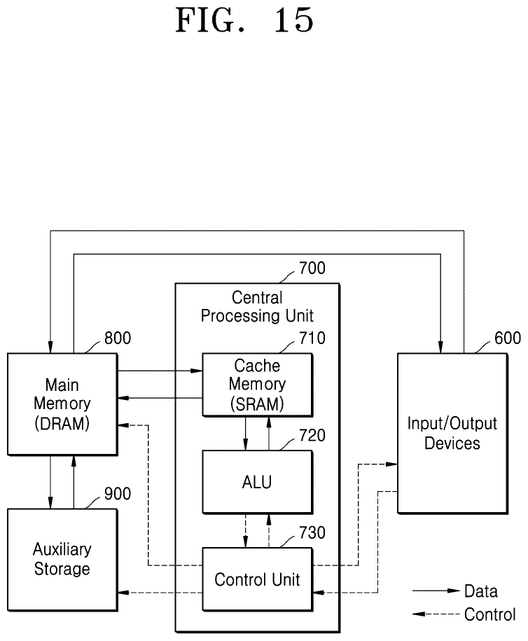

FIGS. 14 and 15 are each a conceptual diagram schematically illustrating a device architecture applicable to an apparatus according to at least one embodiment.

Referring to FIG. 14, an electronic device architecture 500 may include a memory unit 510, an arithmetic logic unit (ALU) 520, and a control unit 530. The memory unit 510, the ALU 520, and the control unit 530 may be electrically connected to each other. For example, the electronic device architecture 500 may be implemented as a single chip including the memory unit 510, the ALU 520, and the control unit 530.

Specifically, the memory unit 510, the ALU 520, and the control unit 530 may be interconnected by a metal line on an on-chip and communicate directly with each other. The memory unit 510, the ALU 520, and the control unit 530 may be integrated on one substrate in a monolithic manner and constitute a single chip. An input/output device 600 may be connected to the electronic device architecture (chip) 500. The memory unit 510 may include both of a main memory and a cache memory. Such electronic device architecture (chip) 500 may be an on-chip memory processing unit. The memory unit 510, the ALU 520, and the control unit 530 may each include the electronic device described above.

Referring to FIG. 15, a cache memory 710, an ALU 720, and a control unit 730 may constitute a central processing unit (CPU) 700, and the cache memory 710 may include static random access memory (SRAM). A main memory 800 and an auxiliary storage 900 may be provided separately from the CPU 700. The main memory 800 may be dynamic random access memory (DRAM), and may include the semiconductor device described above. In some cases, the electronic device architecture may be implemented in a form in which computing unit elements and memory unit elements are adjacent to each other on a single chip without separating sub-units.

According to at least one embodiment, as the oxide thin film is manufactured by using microwaves, the oxide thin film may be manufactured at a low temperature.

According to at least one embodiment, as the oxide thin film is manufactured at a low temperature, oxidation of layers other than the oxide thin film may be prevented.

As the crystallization process of the oxide layer and the phase transition process of the oxide layer are controlled separately at different pressures from each other, types and contents of the crystal structures included in the oxide layer may be controlled.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A manufacturing method of an oxide thin film, the manufacturing method comprising:
forming an amorphous oxide layer on a base layer, the amorphous oxide layer having an amorphous phase;
raising a temperature of the amorphous oxide layer using microwaves at a first pressure; and
forming a crystal structure in the oxide thin film by cooling the temperature-raised oxide layer at a second pressure different from the first pressure.

2. The manufacturing method of claim 1, wherein the second pressure is greater than the first pressure.

3. The manufacturing method of claim 1, wherein the second pressure is at least 30 atmospheres (atm) greater than the first pressure.

4. The manufacturing method of claim 1, wherein the first pressure is within a range of about 0.001 atmospheres (atm) to about 2 atm.

5. The manufacturing method of claim 1, wherein the first pressure is within a range of about 0.01 atmospheres (atm) to about 2 atm.

6. The manufacturing method of claim 1, wherein the raising of the temperature of the amorphous oxide layer includes raising the temperature of the amorphous oxide layer to be within a range of about 200° C. to about 500° C.

7. The manufacturing method of claim 1, wherein the microwaves have a frequency band of about 2 gigahertz (GHz) to about 6 GHz.

8. The manufacturing method of claim 1, further comprising:
maintaining a temperature of the temperature-raised oxide layer for a first period of time.

9. The manufacturing method of claim 8, wherein, the first period of time further includes changing a variable pressure applied to the temperature-raised oxide layer during the first period of time.

10. The manufacturing method of claim 9, wherein the changing the variable pressure includes increasing the variable pressure during the first period of time.

11. The manufacturing method of claim 9, wherein a minimum value of the variable pressure is the first pressure.

12. The manufacturing method of claim 9, wherein a maximum value of the variable pressure is the second pressure.

13. The manufacturing method of claim 1, wherein a dielectric constant of the oxide thin film is 30 or greater.

14. The manufacturing method of claim 1, wherein the temperature-raised oxide layer includes a first crystal structure, and
the crystal structure formed in the oxide thin film is different from the first crystal structure.

15. The manufacturing method of claim 1, wherein a dominant crystal structure of the crystal structure formed in the oxide thin film is an orthorhombic crystal structure.

16. The manufacturing method of claim 1, wherein a remanent polarization change rate of the oxide thin film is 12% or less.

17. The manufacturing method of claim 1, wherein the oxide layer includes a metal oxide.

18. The manufacturing method of claim 1, wherein the oxide layer includes at least one of hafnium (Hf), zirconium (Zr), aluminum (Al), calcium (Ca), cerium (Ce), dysprosium (Dy), erbium (Er), gadolinium (Gd), germanium (Ge), lanthanum (La), scandium (Sc), strontium (Sr), tin (Sn), or yttrium (Y).

19. The manufacturing method of claim 1, wherein the oxide layer includes Hf₁₋ₓMₓO₂, wherein 0<x<1 and M is at least one of zirconium (Zr), aluminum (Al), calcium (Ca), cerium (Ce), dysprosium (Dy), erbium (Er), gadolinium (Gd), germanium (Ge), lanthanum (La), scandium (Sc), silicon (Si), strontium (Sr), tin (Sn), or yttrium (Y).

20. The manufacturing method of claim 1, wherein the base layer is a conductor or a semiconductor.
